(19) United States
(12) Patent Application Publication
(10) Pub. No.: US 2017/0288283 A1
(43) Pub. Date: Oct. 5, 2017

(54) SENSOR FOR DETECTING DEFORMATION OF SEALED SECONDARY BATTERY

(71) Applicant: TOYO TIRE & RUBBER CO., LTD., Osaka-shi, Osaka (JP)

(72) Inventors: Takeshi Fukuda, Osaka-shi (JP); Toshiaki Kawai, Osaka-shi (JP)

(73) Assignee: TOYO TIRE & RUBBER CO., LTD., Osaka-shi, Osaka (JP)

(21) Appl. No.: 15/511,312

(22) PCT Filed: Aug. 4, 2015
(86) PCT No.: PCT/JP2015/072027

§ 371 Date: Mar. 15, 2017

(30) Foreign Application Priority Data
Nov. 25, 2014 (JP) 2014-237629

(51) Int. Cl. H01M 10/48; H01M 2/10; G01R 33/12; H01M 10/0525

(52) U.S. Cl. CPC H01M 10/482; H01M 10/0525; H01M 2/1077; G01R 33/12; H01M 2220/20

(57) ABSTRACT

A sensor for detecting a deformation of a sealed secondary battery, comprising a polymer matrix layer and a detection unit,
wherein
the sealed secondary battery has at least one cell comprising a group of electrodes, and an external packaging body in which the electrode group is held,
the polymer matrix layer is located inside the external packaging body, and contains a filler in a dispersed state, this filler giving a change to an external field in response to a deformation of the polymer matrix layer, and the detection unit is located outside the external packaging body to detect a change of the external field,
the polymer matrix layer is a pressure-sensitive-adhesive-layer-attached polymer matrix layer having a pressure-sensitive-adhesive layer laminated on at least one surface of this polymer matrix layer.

### TECHNICAL FIELD

The present invention relates to a sensor for detecting a deformation of a sealed-type secondary battery; a sensor that is manufactured by this manufacturing method and detects a deformation of a sealed-type secondary battery; a sealed-type secondary battery to which this sensor is fitted; and a method for detecting a deformation of this sealed-type secondary battery.

### BACKGROUND ART

In recent years, a sealed-type secondary battery (hereinafter sometimes referred to merely as a “secondary battery”), a typical example thereof being a lithium ion secondary battery, has been used not only in any mobile instruments such as a portable telephone or book-size personal computer, but also as a power source for any electric motor car such as an electric vehicle or a hybrid car. Single batteries (cells) constituting a secondary battery each have a group of electrodes that is obtained by winding or stacking a positive electrode and a negative electrode onto each other to interpose a separator therebetween, and an external packaging body in which the electrode group is held. In general, a laminated film, or a metallic can is used as the external packaging body, and the electrode group is held, together with an electrolytic solution, in a sealed space in the external packaging body.

A secondary battery is used in the form of a battery module or battery pack including plural cells in an article for which a high-voltage is required, such as a power source for the above-mentioned electric motor car. In such a battery module, plural cells connected in series to each other are held in a package. For example, four cells are connected to each other in the form of two parallel-form-connected lines each made of two-serially-connected-ones of the four cells, or in series of the four cells. In such a battery pack, various devices such as a controller, together with plural battery modules connected in series to each other, are held in a package. In a secondary battery used in a power source for an electric motor car, a package for its battery pack is made into a shape suitable for being mounted into a vehicle.

Such a secondary battery has the following problem: when its electrolytic solution is decomposed by overcharge or some other, a decomposition gas therefrom raises the pressure inside the secondary battery; and with the raise, its cells swell so that the secondary battery is deformed. In this case, when the charging current or the discharge current is not stopped, the secondary battery ignites. As a worse result thereof, the secondary battery goes to burst. It is therefore important for a prevention of the bursting of any secondary battery to detect, with a high sensitivity, a deformation of the secondary battery on the basis of a swelling of its cells in such a manner that a charging current therefor or discharge current therefrom can be stopped at an appropriate time.

Patent Document 1 describes a device for monitoring a secondary battery in which a pressure sensor is located in an inner space of a safety valve to monitor the pressure in the battery. In this patent document, details of the pressure sensor for monitoring the pressure are unclear. In general, however, an electrical pressure sensor is used. In this case, electrical wire from inside the battery is required; thus, it is feared that the battery is lowered in sealing degree.

Patent Document 2 describes an internal pressure detecting system in which a pressure-sensitive electroconductive rubber that changes continuously in resistance value is located inside a battery case. However, according to the system described in this patent document, it is indispensable to lead wiring for detecting a change in the resistance to the outside of a sealed-type battery. Thus, it is feared that the battery is lowered in sealing degree.

Furthermore, Patent Document 3 describes a tape to be bonded to a member in such a manner that end portions of this tape are fastened to each other in which poorness in the sealing-degree of a battery is detectable, using a pH responsive polymer. This tape is somewhat effective for detecting the sealing-degree poorness; however, the tape makes it impossible to detect other information pieces on the inside of the battery, for example, information pieces on the internal pressure of the battery or a deterioration of electrodes thereof.

### PRIOR ART DOCUMENTS

### Patent Documents

Patent Document 1: JP-A-2002-289265

Patent Document 2: JP-A-2001-345123

Patent Document 3: JP-A-2009-016199

### SUMMARY OF THE INVENTION

### Problems to be Solved by the Invention

About a sensor for detecting a deformation of a secondary battery, it is required to make the size thereof small not to press the secondary battery into a small volume. Additionally, the sensor needs to be fitted to an arbitrarily-selected site of the secondary battery, for example, an empty volume space thereof.

In light of the actual situation, the present invention has been made. An object thereof is to provide a sensor that is for detecting a deformation of a sealed secondary battery, that can be located at any site inside the sealed secondary battery and further that exhibits an excellent property stability by fixing the position of this sensor surely while the sensor is made thin; a sealed secondary battery to which this sensor is fitted; and a method for detecting a deformation of the sealed secondary battery.

### Means for Solving the Problems

The above-mentioned object can be attained by the present invention, which is described hereinafter. The present invention relates to a sensor for detecting a deformation of a sealed secondary battery, comprising polymer matrix layer and a detection unit; wherein the sealed secondary battery has at least one cell comprising a group of electrodes, and an external packaging body in which the electrode group is held; the polymer matrix layer is located inside the external packaging body, and contains a filler in a dispersed state, this filler giving a change to an external field in response to a deformation of the polymer matrix layer, and the detection unit is located outside the external packaging body to detect a change of the external field; the polymer matrix layer is a pressure-sensitive-adhesive-layer-attached polymer matrix layer having a pressure-sensitive-adhesive layer laminated on at least one surface of this polymer matrix layer.

Inside the cell having the electrode group and the external packaging body, in which the electrode group is held, the polymer matrix layer is fixed through the pressure-sensitive-adhesive layer onto the electrode group inside the external packaging body. At this time, the polymer matrix layer is fixed in the state of being sandwiched between the external packaging body and the electrode group, as needed.

When the cell is deformed by, for example, a deterioration or deformation of the electrode group or a deterioration of the electrolytic solution, the polymer matrix layer is deformed accordingly inside the external packaging body. A change of the external field which follows the deformation of the polymer matrix layer is detected through the detection unit located outside the external packaging body. Since this sensor has a structure in which the external field change is detected in this way, electrical wiring is not required from the polymer matrix layer to the detection unit. Consequently, this structure does not hinder the sealed configuration. Additionally, the polymer matrix layer is located at the inside of the external packaging body, on which the deformation of the cell acts, so that the cell deformation is detectable with a high sensitivity. Furthermore, the polymer matrix layer fixed through the pressure-sensitive-adhesive layer as described above does not press the cell into a small volume and further this layer is restrained from being shifted out of position by, e.g., vibration. Thus, the sensor is made stable in properties.

In the sealed secondary battery deformation detecting sensor according to the present invention, it is preferred that the polymer matrix layer comprises a magnetic filler as the filler, and the detection unit detects a change of a magnetic field as the external field. This structure makes it possible to detect a change of the magnetic field which follows the deformation of the polymer matrix layer without using wiring. Moreover, this structure makes it possible to use a Hall element, which is wide in sensitivity range, as the detection unit to attain the detection with a high sensitivity over a wider range.

In the sealed secondary battery deformation detecting sensor, it is preferred that the ratio of the thickness of the pressure-sensitive-adhesive layer to the thickness of the polymer matrix layer is from 0.01 to 10. If the thickness ratio is more than 10, a deformation of, e.g., the electrode group is not sufficiently conducted with ease through the pressure-sensitive-adhesive layer to the polymer matrix layer, so that the magnetic flux density may not be sufficiently changed. If the thickness ratio is less than 0.01, the polymer matrix layer is, for example, shifted out of position, so that the sensor sensitivity may become unstable.

In the sealed secondary battery deformation detecting sensor, it is preferred that the thickness of the polymer matrix layer is from 0.01 to 0.4 mm, the thickness of the pressure-sensitive-adhesive layer is from 0.005 to 0.1 mm, and the thickness of the pressure-sensitive-adhesive-layer-attached polymer matrix layer is from 0.015 to 0.5 mm. If the thickness of the polymer matrix layer is less than 0.01 mm, the magnetic flux density may not be sufficiently changed. If the thickness is more than 0.4 mm, the volume of the sensor in the secondary battery is increased to tend to lower the energy density of the battery. If the thickness of the pressure-sensitive-adhesive layer is less than 0.005 mm, the polymer matrix layer is, for example, shifted out of position so that the sensor sensitivity may become unstable. If the thickness is more than 0.1 mm, a deformation of, e.g., the electrode group is not sufficiently conducted with ease through the pressure-sensitive-adhesive layer to the polymer matrix layer, so that the magnetic flux density may not be sufficiently changed. In the same manner, if the total of the thickness of the polymer matrix layer and that of the pressure-sensitive-adhesive layer is less than 0.015 mm, these layers tend to be deteriorated in handleability. If this total thickness is more than 0.5 mm, the volume of the sensor in the secondary battery is increased to tend to lower the energy density of the battery. In order to make the magnetic flux density change quantity and the battery energy density sufficient, the thickness of the polymer matrix layer is set into a range preferably from 0.1 to 0.3 mm.

In the sealed secondary battery deformation detecting sensor, it is preferred that the pressure-sensitive-adhesive layer has an elastic modulus of 0.01 to 5 MPa. By setting the elastic modulus of the pressure-sensitive-adhesive layer into this range, the polymer matrix layer can be prevented, with a higher certainty, from being shifted out of position while the handleability of the pressure-sensitive-adhesive layer is ensured. In order to set the elastic modulus of the pressure-sensitive-adhesive layer into the range, it is preferred that the pressure-sensitive-adhesive layer comprises a polyurethane obtained by causing an active-hydrogen-containing compound to react with an isocyanate component, and the active-hydrogen-containing compound contains a monool component.

In the sealed secondary battery deformation detecting sensor, it is preferred that the pressure-sensitive-adhesive-layer-attached polymer matrix layer is fixed onto a curved portion of the electrode group through the pressure-sensitive-adhesive layer. This structure makes effective use of the empty volume space inside the battery, to prevent the fixation of the wound electrode group or the stacking of the electrode group effectively from being shifted out of position while the energy density of the battery is restrained from being lowered.

The sealed secondary battery according to the present invention is a battery to which the above-mentioned deformation detecting sensor. The form thereof may be a single battery module, or may be a battery pack including plural battery modules. In this sealed secondary battery, a deformation of a member inside the cell is detected through the deformation detecting sensor. In addition thereto, the deformation detecting sensor does not press the secondary battery into a small volume so that the energy density thereof is heightened.

The secondary battery deformation detecting method according to the present is a method for detecting a deformation of a secondary battery having at least one cell comprising a group of electrodes and an external packaging body in which the electrode group is held, wherein a pressure-sensitive-adhesive-layer-attached polymer matrix layer is fixed to an inside of the external packaging body; a polymer matrix layer which the pressure-sensitive-adhesive-layer-attached polymer matrix layer has comprises a filler in a dispersed state, this filler giving a change to an external field in response to a deformation of the polymer matrix layer; and a change of the external field which follows the deformation of the polymer matrix layer is detected, and on the basis of the detection, the deformation of the sealed secondary battery is detected. It is preferred, in particular, for the polymer matrix layer to comprise a magnetic filler as the filler.

The polymer matrix layer is fixed onto the electrode group through the pressure-sensitive adhesive layer. When the cell and the secondary battery are deformed by, for example, a deterioration or deformation of the electrode group or a deterioration of the electrolytic solution, the polymer matrix layer is deformed accordingly and then a change of the external field which follows the deformation of the polymer matrix layer is detected. In this way, the deformation of the cell is detectable with a high sensitivity. In order to enhance this function further, the polymer matrix layer preferably contains a magnetic filler as the filler.

### BRIEF DESCRIPTION OF THE DRAWINGS

FIG. 1 is a sectional view illustrating an example of a site of a secondary battery to which a polymer matrix layer is bonded through a pressure-sensitive-adhesive layer.

FIG. 2 is a sectional view illustrating another example of the site to which the polymer matrix layer is bonded through the pressure-sensitive-adhesive layer.

FIG. 3 is a sectional view illustrating an example of a pressure-sensitive-adhesive-layer-attached polymer matrix layer according to the present invention.

### MODE FOR CARRYING OUT THE INVENTION

Hereinafter, an embodiment of the present invention will be described.

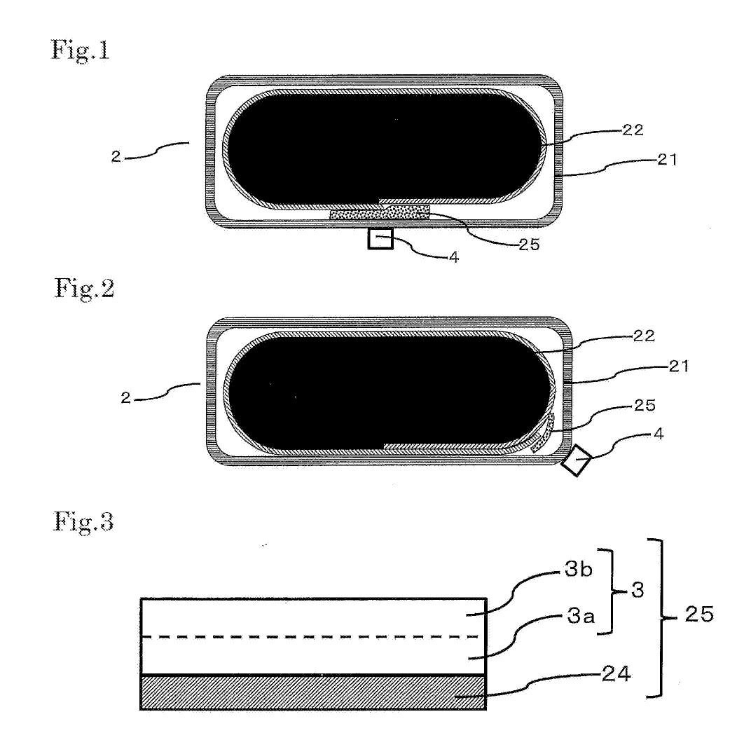

Cells 2 illustrated in FIGS. 1 and 2 each have a group of electrodes 22 which is produced by winding or stacking a positive electrode and a negative electrode onto each other to interpose a separator therebetween, and an external packaging body 21 in which the electrode group 22 is held. The electrode group 22 is held together with an electrolytic solution. For the external packaging body 21 of each of the cells 2, a laminated film, such as an aluminum laminated foil piece, is used. Instead of this film, however, a cylindrical or rectangular type metallic can may be used.

A sealed secondary battery including this cell 2 is a lithium ion secondary battery usable as a power source for electric motor cars, and is mounted to a car in the form of a battery pack. In the battery pack, plural battery modules connected in series to each other are held, together with various devices such as a controller, in a package. The package for the battery pack is made into a shape suitable for being mounted to the car, for example, a shape matched with the shape of a space below the floor of the car. In the present invention, the sealed secondary battery is not limited to any nonaqueous electrolytic solution secondary battery such as a lithium ion battery, and may be an aqueous electrolytic solution secondary battery such as a nickel-hydrogen battery.

As illustrated in FIG. 1, a deformation detecting sensor is fitted to the cell 2 configured as one member of the sealed secondary battery. The deformation detecting sensor has a pressure-sensitive-adhesive-layer-attached polymer matrix layer 25 and a detection unit 4. The detection unit 4 is bonded a surface of the cell 2 (an external surface of the external packaging body). For the bonding, an adhesive or adhesive tape is used as needed. The pressure-sensitive-adhesive-layer-attached polymer matrix layer 25 is made into, e.g., a sheet form. In the example illustrated in FIG. 1, this layer is bonded to the wound electrode group 22 to fasten end portions of the electrode group 22 onto each other. In the example illustrated in FIG. 2, end portions of the wound electrode group 22 are present at a curved portion of the cell. The pressure-sensitive-adhesive-layer-attached polymer matrix layer 25 is bonded onto the curved portion to fasten end portions of the wound electrode group 22 onto each other. The electrode group may be made into not the winding structure but a stacked structure.

A pressure-sensitive-adhesive-layer-attached polymer matrix layer 25 illustrated in FIG. 3 is composed of a polymer matrix layer 3 and a pressure-sensitive-adhesive layer 24. The polymer matrix layer 3 is fixed onto an electrode group through the pressure-sensitive-adhesive layer 24, and contains a filler in a dispersed state, this filler giving a change to an external field in response to a deformation of the polymer matrix layer 3. The detection unit 4 detects a change of the external field. The detection unit 4 is located apart from the polymer matrix layer 3 to such an extent that the change of the external field is detectable, and is preferably bonded to a site of the cell 2 which is relatively strong not to receive an effect of a deformation of the cell 2 easily.

When a member inside the cell, for example, the electrode group 22 deforms, the polymer matrix layer 3 is deformed accordingly. The detection unit 4 detects a change of the external field which follows the deformation of the polymer matrix layer 3. A detection signal outputted from the detection unit 4 is sent to a control unit not illustrated. When it is detected through the detection unit 4 that the external field change is a change having a set value or more, a switching circuit connected to the control unit and not illustrated cuts off the passage of electric current to stop the charge current or discharge current. In this way, the deformation of the secondary battery, which is based on swell of the cell 2, is detected with a high sensitivity to prevent the secondary battery from being burst. This deformation detecting sensor does not press the secondary battery into a small volume; thus, the sensor is restrained from being shifted out of position to stabilize properties of the sensor.

In the example in each of FIGS. 1 and 2, the single polymer matrix layer 3 and the single detection unit 4 have been illustrated. However, plural polymer matrix layers and plural detection units may be used in accordance with the shape and size of the secondary battery, and other conditions. At this time, the polymer matrix layer 3 located as illustrated in FIG. 1 and the polymer matrix layer 3 located as illustrated in FIG. 2 may be together located. Furthermore, plural polymer matrix layers 3 may be located to the same single cell 2, or plural detection units 4 may detect a change of the external field which follows a change of the same polymer matrix layer 3.

In the present embodiment, the polymer matrix layer 3 contains a magnetic filler as the above-mentioned filler, and the detection unit 4 detects a change of a magnetic field as the external field, i.e., the amount of a change in the magnetic flux density. In this case, the polymer matrix layer 3 is preferably a magnetic elastomer layer in which a magnetic filler is dispersed in a matrix made of an elastomer component.

Examples of the magnetic filler include rare earth based, iron based, cobalt based, nickel based, and oxide based fillers. The rare earth based fillers, which give a higher magnetic force, are preferred. The shape of the magnetic filler is not particularly limited, and may be any one of the following: spherical, flat, needle, columnar and indeterminate shapes. The average particle diameter of the magnetic filler is preferably from 0.02 to 500 μm, more preferably from 0.1 to 400 μm, even more preferably from 0.5 to 300 μm. If the average particle diameter is less than 0.02 μm, the magnetic filler tends to be lowered in magnetic properties. If the average particle diameter is more than 500 μm, the magnetic elastomer layer tends to be lowered in mechanical properties to become brittle.

The sealed secondary battery deformation detecting sensor according to the present invention has a pressure-sensitive-adhesive-layer-attached polymer matrix layer and a detection unit. As a polymer matrix which the pressure-sensitive-adhesive-layer-attached polymer matrix layer has, for example, an elastomer component is usable. As the elastomer component, any component is usable. The elastomer component may be a thermoplastic elastomer, a thermosetting elastomer, or a mixture of these elastomers. Examples of the thermoplastic elastomer include styrene type, polyolefin type, polyurethane type, polyester type, polyamide type, polybutadiene type, polyisoprene type, and fluorine-contained rubber type thermoplastic elastomers. Examples of the thermosetting elastomer include diene synthetic rubbers such as polyisoprene rubber, polybutadiene rubber, styrene-butadiene rubber, polychloroprene rubber, nitrile rubber and ethylene-propylene rubber; non-diene rubbers such as ethylene-propylene rubber, butyl rubber, acrylic rubber, polyurethane rubber, fluorine-contained rubber, silicone rubber and epichlorohydrin rubber; and natural rubbers. Out of these rubbers, preferred are thermosetting elastomers since the elastomers make it possible to restrain the magnetic elastomer from flowing down in accompaniment with the generation of heat from the battery or an excessive load thereon. More preferred is polyurethane rubber (referred to also as polyurethane elastomer) or silicone rubber (referred to also as silicone elastomer).

The polyurethane elastomer is obtained by causing an active-hydrogen-containing compound to react with an isocyanate component. When the polyurethane elastomer is used as the elastomer component, the active-hydrogen-containing compound and the magnetic filler are mixed with each other and then the isocyanate component is blended into the mixture to yield a mixed liquid. The mixed liquid may be obtained by blending the magnetic filler into the isocyanate component and then blending the active-hydrogen-containing compound into the resultant mixture. Even when either of these methods is used, the magnetic filler is mixed with the polymer matrix precursor containing the active-hydrogen-containing compound and the isocyanate component to prepare the mixture liquid. When a silicone elastomer is used as the elastomer component, the mixture liquid can be prepared by putting the magnetic filler into a precursor of the silicone elastomer to mix these components with each other. As needed, a solvent may be added to the raw materials for the mixture liquid.

An isocyanate component usable for the polyurethane elastomer may be a compound known in the field of polyurethane. Examples thereof include aromatic diisocyanates such as 2,4-toluene diisocyanate, 2,6-toluene diisocyanate, 2,2′-diphenylmethane diisocyanate, 2,4′-diphenylmethane diisocyanate, 4,4′-diphenylmethane diisocyanate, 1,5-naphthalene diisocyanate, p-phenylene diisocyanate, m-phenylene diisocyanate, p-xylylene diisocyanate and m-xylylene diisocyanate; aliphatic diisocyanates such as ethylene diisocyanate, 2,2,4-trimethylhexamethylene diisocyanate and 1,6-hexamethylene diisocyanate; and alicyclic diisocyanates such as 1,4-cyclohexane diisocyanate, 4,4′-dicyclohexylmethane diisocyanate, isophorone diisocyanate and norbornane diisocyanate. These may be used singly or in the form of a mixture of two or more thereof. The isocyanate component may be a modified component such as a urethane modified, allophanate modified, biuret modified or isocyanurate modified component. The isocyanate component is preferably 2,4-toluene diisocyanate, 2,6-toluene diisocyanate, 4,4′-diphenylmethane diisocyanate, and is more preferably 2,4-toluene diisocyanate, or 2,6-toluene diisocyanate.

In the present invention, the active-hydrogen-containing compound may be a known compound in the field of polyurethane. Examples thereof are polyether polyols, typical examples thereof including polytetramethylene glycol, polypropylene glycol, polyethylene glycol, and any copolymer made from propylene oxide and ethylene oxide; polyester polyols, typical examples thereof including polybutylene adipate, polyethylene adipate, and 3-methyl-1,5-pentane adipate; polyester polycarbonate polyols, examples thereof including reactants each made from a polyester glycol such as polycaprolactone polyol or polycaprolactone, and an alkylene carbonate; polyester polycarbonate polyols each obtained by causing ethylene carbonate to react with a polyhydric alcohol, and next causing the resultant reaction mixture to react with an organic dicarboxylic acid; polycarbonate polyols each obtained by interesterification reaction between a polyhydroxyl compound and an aryl carbonate; and other high-molecular-weight polyols. These may be used singly or in any combination of two or more thereof.

Besides these high-molecular-weight polyol components, the following may be used as the active-hydrogen-containing compound: ethylene glycol, 1,2-propylene glycol, 1,3-propylene glycol, 1,4-butanediol, 1,6-hexanediol, neopentyl glycol, 1,4-cyclohexanedimethanol, 3-methyl-1,5-pentanediol, diethylene glycol, triethylene glycol, 1,4-bis(2-hydroxyethoxy)benzene, trimethylolpropane, glycerin, 1,2,6-hexanetriol, pentaerythritol, tetramethylolcyclohexane, methyl glucoside, sorbitol, mannitol, dulcitol, sucrose, 2,2,6,6-tetrakis(hydroxymethyl)cyclohexanol, triethanolamine, and other low-molecular-weight polyol components; and ethylenediamine, tolylenediamine, diphenylmethanediamine, diethylenetriamine, and other low-molecular-weight polyamine components. These may be used singly or in any combination of two or more thereof. Furthermore, the following may be blended thereinto: 4,4′-methylenebis(o-chloroaniline) (MOCA), 2,6-dichloro-p-phenylenediamine, 4,4′-methylenebis(2,3-dichloroaniline), 3,5-bis(methylthio)-2,4-toluenediamine, 3,5-bis(methylthio)-2,6-toluenediamine, 3,5-diethyltoluene-2,4-diamine, 3,5-diethyltoluene-2,6-diamine, trimethylene glycol-di-p-aminobenzoate, polytetramethylene oxide-di-p-aminobenzoate, 1,2-bis(2-aminophenylthio)ethane, 4,4′-diamino-3,3′-diethyl-5,5′-dimethyldiphenylmethane, N,N′-di-sec-butyl-4,4′-diaminodiphenylmethane, 4,4′-diamino-3,3′-diethyldiphenylmethane, 4,4′-diamino-3,3′-diethyl-5,5′-dimethyldiphenylmethane, 4,4′-diamino-3,3′-diisopropyl-5,5′-dimethyldiphenylmethane, 4,4′-diamino-3,3′,5,5′-tetraethyldiphenylmethane, 4,4′-diamino-3,3′,5,5′-tetraisopropyldiphenylmethane, m-xylylenediamine, N,N′-di-sec-butyl-p-phenylenediamine, m-phenylenediamine, p-xylylenediamine, and other polyamines. About the active-hydrogen-containing compound, preferred are polytetramethylene glycol, polypropylene glycol, any copolymer made from propylene oxide and ethylene oxide, 3-methyl-1,5-pentane adipate; and more preferred are polypropylene, and any copolymer made from propylene oxide and ethylene oxide.

When the polyurethane elastomer is used, the NCO index thereof is preferably from 0.3 to 1.2, more preferably from 0.35 to 1.1, even more preferably from 0.4 to 1.05. If the NCO index is less than 0.3, the magnetic elastomer tends to be insufficiently cured. If the NCO index is more than 1.2, the polymer matrix layer becomes high in elastic modulus so that the sensor sensitivity tends to be lowered.

The amount of the magnetic filler in the magnetic elastomer is preferably from 1 to 2000 parts by weight, more preferably from 5 to 1500 parts by weight for 100 parts by weight of the elastomer component. If this amount is less than 1 part by weight, the sensor tends not to detect a change of the magnetic field easily. If the amount is more than 450 parts by weight, the magnetic elastomer itself may become brittle.

The detection unit 4 for detecting a change of the magnetic field can make use of, for example, a magnetoresistive element, a Hall element, an inductor, an MI element, or a flux gate sensor. Examples of the magnetoresistive element include semiconductor compound magnetoresistive elements, anisotropic magnetoresistive elements (AMRs), giant magnetoresistive elements (GMRs), and tunnel magnetoresistive elements (TMRs). Out of these examples, a Hall element is preferred. This element is useful for the detection unit 4 that is a unit having a high sensitivity in a wide range.

The magnetic filler may be introduced into the elastomer after magnetized. Preferably, the magnetic filler is magnetized after introduced into the elastomer. When the magnetic filler is magnetized after introduced into the elastomer, the magnetism of the magnet is easily controlled to make the detection of the magnetic field easy.

The method for magnetizing the magnetic filler is not particularly limited, and may be performed, using an ordinarily usable magnetizing machine, such as a machine “ES-10100-15SH” manufactured by Denshijiki Industry Co., Ltd. or “TM-YS4E” manufactured by Tamagawa Co., Ltd. Usually, a magnetic field having a magnetic flux density of about 1 to 8 T is applied to the filler.

The thickness of the polymer matrix layer 3 is preferably from 0.01 to 0.4 mm, more preferably from 0.05 to 0.35 mm, even more preferably from 0.1 to 0.3 mm. If the thickness is less than 0.01 mm, the magnetic flux density of this layer may be insufficiently changed. If the thickness is more than 0.4 mm, the volume of the sensor in the cell increases to tend to lower the energy density of the battery.

The magnetic filler in the polymer matrix layer may be evenly dispersed or unevenly dispersed. For the uneven dispersion of the filler, a method is usable which includes: introducing the filler into an elastomer component, and allowing the resultant to stand still at room temperature or a predetermined temperature to precipitate the filler naturally by the weight of the filler. The uneven-dispersion proportion of the filler is adjustable by changing a temperature or period for the standing-still. The filler may be unevenly dispersed, using a physical force such as centrifugal force or magnetic force. When the filler is unevenly dispersed, the filler uneven-dispersion proportion in a high-filler-concentration region of the polymer matrix layer, which is a single layer, is preferably more than 50, more preferably 60 or more, even more preferably 70 or more. In this case, the filler uneven-dispersion proportion in a low-filler-concentration region thereof is less than 50. The filler uneven-dispersion proportion in the high-filler-concentration region is 100 at maximum while that in the low-filler-concentration region is 0 at minimum. The polymer matrix layer may be a polymer matrix layer having a structure in which, e.g., two layers are laminated onto each other. In this case, a high-filler-concentration polymer matrix layer may be laminated onto a low-filler-concentration polymer matrix layer, or a polymer matrix layer containing no filler may be laminated onto a polymer matrix layer containing a filler. In the case of laminating two polymer matrix layers onto each other, the filler uneven-dispersion proportion in a high-filler-concentration region of this laminate ranges preferably from 60 to 100 when the filler uneven-dispersion proportion in the whole of the laminate is regarded as 100. Whether the deformation detecting sensor uses the case of dispersing the filler unevenly in the single polymer matrix layer, or uses the laminated polymer matrix layer in which the filler is unevenly dispersed, it is preferred to locate the polymer matrix layer to bring a high-filler-concentration region thereof into contact with the electrode group since the sensor is heightened in detection sensitivity. In the example illustrated in FIG. 3, it is preferred to locate a high-filler-concentration region on a layer-3a-side of the polymer matrix layer 3.

The filler uneven-dispersion proportion is measured by the following method: A scanning electron microscopy and energy dispersive X-ray analyzing spectrometer (SEM-EDS) is used to observe a cross section of the polymer matrix layer at a magnifying power of 100. About each of the entire region of the cross section in the thickness direction thereof, and four regions obtained by quadrisecting the cross section in the thickness direction, the existing amount of a metal element inherent in the filler (for example, an Fe element in the case of the magnetic filler in the present embodiment) is gained by elementary analysis. In connection with the resultant existing amounts, the ratio of the element existing amount in one of both-side regions of the cross section to that in the entire region in the thickness direction is calculated out. This ratio is defined as the filler uneven-dispersion proportion in the one side region. The filler uneven-dispersion proportion in the other side region is also gained in the same way as described above.

The polymer matrix layer 3 may be a non-foamed body, which contains air bubbles. This layer may be a foamed body, which contains air bubbles, to heighten the sensor in stability and sensitivity and further lighten the sensor. The foamed body may be generally a resin foam. It is preferred to use a thermosetting resin foam, considering compressive permanent set and other properties thereof. Examples of the thermosetting resin foam include a polyurethane resin foam, and a silicone resin foam. Out of these foams, a polyurethane resin foam is preferred. For the polyurethane resin foam, the above-mentioned isocyanate component and active-hydrogen-containing compound are usable.

As a catalyst used for the polyurethane resin foam, a known catalyst is usable without receiving any restriction. Examples thereof include tertiary amine catalysts, such as triethylenediamine(1,4-diazabicyclo[2,2,2]octane), N,N,N′,N′-tetramethylhexanediamine, and bis(2-dimethylaminoethyl) ether); and metal catalysts such as tin octylate, lead octylate, zinc octylate, and bismuth octylate. These catalysts may be used singly or in any combination of two or more thereof.

Examples of a commercially available product of the catalyst include products “TEDA-L33” manufactured by Tosoh Corp., “NIAX CATALYST A1” manufactured by Momentive Performance Materials Inc., “KAORISER NO. 1” and “KAORISER NO. 30P” manufactured by Kao Corp., “DABCO T-9” manufactured by Air Products Industry Co., Ltd., “BTT-24” manufactured by Toei Chemical Industry Co., Ltd., and “PUCAT 25” manufactured by Nihon Kagaku Sangyo Co., Ltd.

A foam stabilizer used for the polyurethane resin foam may be a foam stabilizer used to produce any ordinary polyurethane resin foam, for example, a silicone foam stabilizer, and a fluorine-containing foam stabilizer. A silicone surfactant or fluorine-containing surfactant used as the silicone foam stabilizer or fluorine-containing foam stabilizer has, in the molecule thereof, a moiety soluble in polyurethane-type material, and a moiety insoluble therein. The insoluble moiety causes polyurethane-type material to be evenly dispersed to lower the polyurethane-type material in surface tension, thereby generating air bubbles easily and not breaking the bubbles easily. Of course, if the surface tension is excessively lowered, air bubbles are not easily generated. When, for example, the silicone surfactant is used in the resin foam in the present invention, its dimethylpolysiloxane structure as the insoluble moiety makes it possible to make the diameter of the air bubbles small, and make the number of the air babbles large.

Examples of a commercially available product of the silicone foam stabilizer include products “SF-2962”, “SRX 274DL”, “SF-2965”, “SF-2904”, “SF-2908”, “SF-2904”, and “L5340” each manufactured by Dow Corning Toray Co., Ltd.; and “TEGOSTABs (registered trade name) B8017, B-8465 and B-8443” manufactured by Evonik Degussa GmbH. Examples of a commercially available product of the fluorine-containing surfactant include products “FC430” and “FC4430” manufactured by 3M; and “FC142D”, “F552”, “F554”, “F558”, “F561”, and “R41” manufactured by DIC Corp.

The blend amount of the foam stabilizer is preferably from 1 to 15 parts by mass, more preferably from 2 to 12 parts by mass for 100 parts by mass of the resin component(s). If the blend amount of the foam stabilizer is less than 1 part by mass, air bubbles are not sufficiently generated. If the amount is more than 15 parts by mass, the foam stabilizer may bleed out.

The bubble content in the foam constituting the polymer matrix layer 3 is preferably from 20 to 80% by volume. When the bubble content is 20% or more by volume, the polymer matrix layer 3 is soft to be easily deformed to heighten the sensor sensitivity favorably. When the bubble content is 80% or less by volume, the polymer matrix layer 3 is restrained from becoming brittle to be heightened in handleability and stability. The bubble content is calculated out by measuring the specific gravity of the layer 3 in accordance with JIS Z-8807-1976, and using this value and the specific gravity value of the non-foamed body.

The average bubble diameter of the foamed body constituting the polymer matrix layer 3 is preferably from 50 to 300 μm. The average opening diameter thereof is preferably from 15 to 100 μm. If the average bubble diameter is less than 50 μm or the average opening diameter is less than 15 μm, the amount of the foam stabilizer tends to increase to deteriorate the stability of properties of the sensor. If the average bubble diameter is more than 300 μm or the average opening diameter is more than 100 μm, the sensor tends to be decreased in contact area with a detection target, such as a cell, to be lowered in stability. The average bubble diameter and the average opening diameter are obtained by observing a cross section of the polymer matrix layer through an SEM at a magnifying power of 100, using an image analysis software to measure, about the resultant image, the respective bubble diameters of all bubbles present inside any area of the cross section and the respective opening diameters of all open bubble-cells inside the same area, and then calculating the respective average values of the bubble diameters and the opening diameters.

The closed bubble-cell proportion in the foamed body constituting the polymer matrix layer 3 is preferably from 5 to 70%. This case makes it possible that the polymer matrix layer 3 exhibits an excellent stability while ensuring good compressibility. Moreover, the filler proportion by volume in the foamed body constituting the polymer matrix layer 3 is preferably from 1 to 30% by volume.

The above-mentioned polyurethane resin foam can be produced by an ordinary method for producing a polyurethane resin foam except that the magnetic filler is incorporated thereinto. The method for forming the magnetic-filler-incorporated polyurethane resin foam includes, for example, the following steps (i) to (v):

step (i) of producing an isocyanate-group-containing urethane prepolymer from a polyisocyanate component and an active hydrogen component;

primary stirring step (ii) of mixing the isocyanate-group-containing urethane prepolymer, a foam stabilizer, a catalyst, and a magnetic filler with each other, stirring the mixture preliminarily, and stirring the mixture vigorously in a nonreactive gas atmosphere in such a manner that the mixture can take in air bubbles;

step (iii) of adding an active hydrogen component further to the mixture, and stirring the resultant mixture secondarily to prepare a magnetic-filler-containing bubble-dispersed urethane composition;

step (iv) of making the bubble-dispersed urethane composition into a desired shape, and curing the shaped composition to produce a magnetic-filler-containing urethane resin foam; and

step (v) of magnetizing the urethane resin foam to form a magnetic urethane resin foam.

As a method for producing a polyurethane resin foam, known is a chemical foaming method using a reactive foaming agent such as water. It is however preferred to use a mechanical foaming method of stirring, as performed in the steps (ii) and (iii), a mixture containing an isocyanate-group-containing urethane prepolymer, a foam stabilizer, a catalyst and a magnetic filler, and an active hydrogen component mechanically in a nonreactive gas atmosphere. The mechanical foaming method is simpler and easier in material-shaping operation than the chemical foaming method, and does not make use of water as a foaming agent to yield a strong shaped body which has fine bubbles and is excellent in impact resilience (restorability) and others.

Initially, as performed in the step (i), an isocyanate-group-containing urethane prepolymer is produced from a polyisocyanate component and an active hydrogen component. As performed in the primary stirring step (ii), the isocyanate-group-containing urethane prepolymer is mixed with a foam stabilizer, a catalyst, and a magnetic filler. The mixture is preliminarily stirred, and vigorously stirred in a nonreactive gas atmosphere in such a manner that the mixture can take in air bubbles. As performed in the secondary stirring step (iii), an active hydrogen component is further added to the mixture, and the mixture is vigorously stirred to prepare a magnetic-filler-containing bubble-dispersed urethane composition. About a polyurethane resin foam containing a polyisocyanate component, an active hydrogen component and a catalyst, those skilled in the art know a method in which as performed in the steps (i) to (iv), an isocyanate-group-containing urethane prepolymer is beforehand produced and then the polyurethane resin foam is formed. Conditions for the production are appropriately selectable in accordance with the blend materials.

About conditions for the production in the step (i), initially, the blend ratio between the polyisocyanate component and the active hydrogen component is selected to set the ratio of isocyanate groups to active hydrogen radicals (“isocyanate groups”/“active hydrogen radicals”) in the polyisocyanate component into a range from 1.5 to 5, preferably from 1.7 to 2.3. The reaction temperature is preferably from 60 to 120° C., and the reaction period is preferably from 3 to 8 hours. Furthermore, a conventionally known urethanizing catalyst or organic catalyst may be used, examples thereof including lead octylate, which is commercially available with a trade name “BTT-24” from Toei Chemical Industry Co., Ltd.; and products “TEDA-L33” manufactured by Tosoh Corp., “NIAX CATALYST A1” manufactured by Momentive Performance Materials Inc., “KAORISER NO. 1” manufactured by Kao Corp., and “DABCO T-9” manufactured by Air Products Industry Co., Ltd. An apparatus usable in the step (i) may be an apparatus capable of mixing the above-mentioned materials with each other and stirring the materials under conditions as described above to cause the materials to react with each other. The apparatus may be an apparatus usable for an ordinary polyurethane-production.

The method for performing the primary stirring in the step (ii) may be a method using an ordinary mixing machine capable of mixing a liquid resin with a filler. Examples of the machine include a homogenizer, a dissolver, and a planetary mixer.

It is preferred to add the foam stabilizer into a raw-material-group including the isocyanate-group-containing urethane prepolymer, and then stirring (primarily-stirring) the resultant in the step (ii), and further add the active hydrogen component thereto and then stirring the resultant secondarily in the step (iii) since the bubbles taken into the reaction system are not easily released so that effective foaming can be attained.

The nonreactive gas in the step (ii) is preferably a noncombustible gas. Specific examples thereof include nitrogen, oxygen, carbon dioxide gas, rare gases such as helium and argon; and a mixed gas of two or more of these gases. The nonreactive gas is most preferably air from which water has been removed by drying. Conditions for the primary stirring and the secondary stirring, particularly for the primary stirring, may be the same conditions as used to produce a urethane foam by an ordinary mechanical foaming method. Although the conditions are not particularly limited, stirring blades, or a mixing machine having stirring blades is used to stir the components concerned vigorously at a rotational number of 1000 to 10000 rpm for 1 to 30 minutes. Examples of such a machine include a homogenizer, a dissolver, and a mechanical froth foaming machine.

In the step (iv), the method for making the bubble-dispersed urethane composition into a desired shape, such as a sheet shape, is not particularly limited, and may be, for example, a batch-manner method of injecting the above-mentioned liquid into a release-treated mold, and then curing the liquid, or a continuously shaping method of supplying the bubble-dispersed urethane composition continuously onto a release-treated face plate, and then curing the composition. Conditions for the curing are not particularly limited, either, and are preferably a temperature of 60 to 200° C. and a period of 10 minutes to 24 hours. If the curing temperature is too high, the above-mentioned resin foam is thermally deteriorated to be made worse in mechanical strength. If the curing temperature is too low, the resin foam is insufficiently cured. If the curing period is too long, the resin foam is thermally deteriorated to be made worse in mechanical strength. If the curing period is too short, the resin foam is insufficiently cured.

In the step (v), the method for magnetizing the magnetic filler is not particularly limited, and may be performed, using an ordinarily usable magnetizing machine, such as a machine “ES-10100-15SH” manufactured by Denshijiki Industry Co., Ltd. or “TM-YS4E” manufactured by Tamagawa Co., Ltd. Usually, a magnetic field having a magnetic flux density of about 1 to 8 T is applied to the filler. In the step (ii) of producing the magnetic-filler-dispersed liquid after the magnetization, the magnetic filler may be added to raw materials of this liquid. Preferably, the magnetic filler is magnetized in the step (v) from the viewpoint of, e.g., the handling-workability of the magnetic filler in the middle steps.

In the present invention, to such an extent that the flexibility of the polymer matrix layer is not damaged, a sealing material may be fitted to the sensor. The sealing material may be a thermoplastic resin, a thermosetting resin or a mixture of the two resins. Examples of the thermoplastic resin include styrene-, polyolefin-, polyurethane-, polyester-, polyamide-, polybutadiene-, polyisoprene-, and fluororesin-type thermoplastic elastomers; and ethylene/ethyl acrylate copolymer, ethylene/vinyl acetate copolymer, polyvinyl chloride, polyvinylidene chloride, chlorinated polyethylene, fluororesin, polyamide, polyethylene, polypropylene, polyethylene terephthalate, polybutylene terephthalate, polystyrene, and polybutadiene. Examples of the thermosetting resin include diene synthetic rubbers such as polyisoprene rubber, polybutadiene rubber, styrene/butadiene rubber, polychloroprene rubber, and acrylonitrile/butadiene rubber; non-diene rubbers such as ethylene/propylene rubber, ethylene/propylene/diene rubber, butyl rubber, acrylic rubber, polyurethane rubber, fluorine-contained rubber, silicone rubber and epichlorohydrin rubber; and natural rubber, polyurethane resin, silicone resin, and epoxy resin. In the case of using, as the sealing material, the thermoplastic resin, thermosetting resin or mixture thereof, the used resin or mixture is favorably in, e.g., a film form. Such films may be laminated onto each other. The film may be a film including a metal evaporated film in which a metal is evaporated and deposited onto a metal foil piece such as an aluminum foil piece or onto a film as described above.

The pressure-sensitive-adhesive layer is made of a polyurethane obtained by causing an active-hydrogen-containing compound to react with an isocyanate component. The active-hydrogen-containing compound and the isocyanate component may be the same as usable when the above-mentioned polymer matrix layer is formed. In the present invention, it is preferred that the active-hydrogen-containing compound, which is to constitute the pressure-sensitive-adhesive layer, contains a monool component.

The monool component that is a component having one functional group may be a monool component known in the technical field of polyurethane. In the present invention, the monool component is in particular preferably a monool having a polar group such as a nitrile group or nitro group. Specific examples of this monool component include ethylene cyanohydrin (2-cyanoethyl alcohol), 2-hydroxybutyronitrile, 2-hydroxyisobutyronitrile, 3-hydroxybutyronitrile, 3-hydroxyglutaronitrile, 3-hydroxy-3-phenylpropionitrile, o-cyanobenzyl alcohol, m-cyanobenzyl alcohol, p-cyanobenzyl alcohol, 4-(2-hydroxyethyl)benzonitrile, 2-nitroethanol, 2-methyl-2-nitro-1-propanol, 3-nitro-2-butanol, 3-nitro-2-pentanol, o-nitrobenzyl alcohol, m-nitrobenzyl alcohol, p-nitrobenzyl alcohol, 2-methyl-3-nitrobenzyl alcohol, 3-methyl-2-nitrobenzyl alcohol, 3-methyl-4-nitrobenzyl alcohol, 4-methyl-3-nitrobenzyl alcohol, 5-methyl-2-nitrobenzyl alcohol, 3-methoxy-4-nitrobenzyl alcohol, 4,5-dimethoxy-2-nitrobenzyl alcohol, 4-methoxy-3-nitrobenzyl alcohol, 5-hydroxy-2-nitrobenzyl alcohol, 4-hydroxy-3-nitrobenzyl alcohol, and 2-(4-nitrophenyl)ethanol. Some other usable example of the monool component may be a mono-alcohol known for those skilled in the art, such as methanol, ethanol, n-propyl alcohol, or isopropyl alcohol; or a monool compound represented by the following general formula (1):

R¹—(OCH₂CHR²)ₙ—OH (1)

wherein R¹ is a methyl or ethyl group, R²(s) is/are (each) a hydrogen atom or a methyl group, and n is an integer from 1 to 5. Specific examples thereof include diethylene glycol monoethyl ether, diethylene glycol monomethyl ether, dipropylene glycol monoethyl ether, dipropylene glycol monomethyl ether, 2-methoxyethanol, ethylene glycol monoethyl ether, ethylene glycol monobutyl ether, ethylene glycol mono-t-butyl ether, ethylene glycol monophenyl ether, diethylene glycol monobutyl ether, triethylene glycol monobutyl ether, and polyethylene glycol mono-p-isooctylphenyl ether; and any alkylene oxide adduct of a carboxylic acid such as acetic acid, acrylic acid or methacrylic acid.

The thickness of the pressure-sensitive-adhesive layer is preferably from 0.005 to 0.1 mm. If the thickness of the pressure-sensitive-adhesive layer is less than 0.005 mm, the polymer matrix layer may be shifted out of position so that the sensor sensitivity may be stabilized. If the thickness is more than 0.1 mm, a deformation of the electrode group or some other is not sufficiently conducted with ease through the pressure-sensitive-adhesive layer to the polymer matrix layer so that the magnetic flux density may be insufficiently changed.

The thickness of the pressure-sensitive-adhesive-layer-attached polymer matrix layer is preferably from 0.015 to 0.5 mm. If the total of the thickness of the polymer matrix layer and that of the pressure-sensitive-adhesive layer is less than 0.015 mm, these layers tend to be deteriorated in handleability. If this total thickness is more than 0.5 mm, the volume of the sensor in the secondary battery tends to increase to lower the energy density of the battery.

The present invention is never limited to the above-mentioned embodiment. The embodiment may be variously modified or changed as far as the modified or changed embodiment does not depart from the subject matter of the invention.

In the above-mentioned embodiment, the following are shown: an example in which the polymer matrix layer 3 is bonded to the electrode group 22 through the pressure-sensitive-adhesive layer 24 to fasten end portions of the electrode group 22, which is wound, to each other (FIG. 1); and an example in which one end portion of the wound electrode group 22 is present in one of the curved portions of the cell 2, and the polymer matrix layer 3 is bonded to the electrode group 22 to fasten the end portion of the electrode group 22, which is wound, to the other end portion, on the curved portion. However, the present invention is not limited to these examples. For example, a pressure-sensitive-adhesive-layer-attached polymer matrix layer may be sandwiched between a positive electrode and a separator, between a negative electrode and the separator, between the positive electrode and an external packaging body, between the negative electrode and the external packaging body, or between the separator and the external packaging body. This sensor is useful, in particular, for being used as a deformation detecting sensor for a cylindrical or rectangular type cell made by winding a positive electrode, a separator and a negative electrode.

In the above-mentioned embodiment, an example is shown in which a change of a magnetic field is used. However, the deformation detecting sensor may be configured to use a change of any other external field such as an electrical field. For example, a configuration is conceivable in which a polymer matrix layer contains, as a filler, an electroconductive filler such as metal particles, carbon black or carbon nanotubes, and a detection unit detects a change of an electrical field (resistance change or dielectric constant change) as the external field.

### EXAMPLES

Hereinafter, working examples of the present invention will be described. However, the invention is not limited to these examples.

In order to produce a magnetic polyurethane elastomer which would turn to each polymer matrix layer, and each pressure-sensitive-adhesive layer, the following materials were used:

TDI-80: toluene diisocyanate (COSMONATE T-80, manufactured by Mitsui Chemicals, Inc.; 2,4-bodies: 80%),

Active-hydrogen-containing compound A: polyester polyol (F-3010, manufactured by Kuraray Co., Ltd.; OH value: 56; the number of functional groups: 3) made from 3-methyl-1,5-pentanediol, trimethylolpropane, and adipic acid as starting materials;

Active-hydrogen-containing compound B: 3-methyl-1,5-pentane adipate (P-2010, manufactured by Kuraray Co., Ltd.; OH value: 56; the number of functional groups: 2);

Active-hydrogen-containing compound C: ethylene cyanohydrin (manufactured by Tokyo Chemical Industry Co., Ltd.; OH value: 789; the number of functional group(s): 1);

Active-hydrogen-containing compound D: n-propyl alcohol (manufactured by Nacalai Tesque, Inc.; OH value: 933; the number of functional group(s): 1);

Di-n-butyltindilaurate (manufactured by Nacalai Tesque, Inc.); and

Neodymium based filler: MQP-14-12 (manufactured by Molycorp Magnequench; average particle diameter: 50 μm).

### Example 1

### (Production of Pressure-Sensitive-Adhesive Layer)

Into a reactor were put 42.6 parts by weight of the active-hydrogen-containing compound A and 42.6 parts by weight of the active-hydrogen-containing compound B. While these components were stirred, the components were dehydrated under a reduced pressure for 1 hour. Thereafter, the reactor was purged with nitrogen. Next, to the reactor were added 14.8 parts by weight of toluene diisocyanate. While the temperature of the inside of the reactor was kept at 80° C., the reactive components were caused to react with each other for 5 hours to synthesize an isocyanate-terminated prepolymer A (NCO %=3.58%).

A mixed liquid of 15.0 parts by weight of the active-hydrogen-containing compound A, 5.0 parts by weight of the active-hydrogen-containing compound C, and 0.12 part by weight of di-n-butyltin dilaurate was added to 100.0 parts by weight of the prepolymer A dissolved in 60.0 g of ethyl acetate. These components were mixed with each other and defoamed in a planetary centrifugal mixer (manufactured by Thinky Corp.) to prepare a polyurethane composition. This polyurethane composition was dropped down onto a release-treated PET film having a space having a desired thickness. A doctor blade was then used to adjust the dropped composition into a desired thickness. Thereafter, this composition was cured at 80° C. for 3 hours to yield an adhesive polyurethane resin (pressure-sensitive-adhesive layer).

### (Production of Pressure-Sensitive-Adhesive-Layer-Attached Polymer Matrix Layer)

To a mixed liquid of 189.4 parts by weight of the active-hydrogen-containing compound A and 0.29 part by weight of di-n-butyltin dilaurate were added 537.5 parts by weight of the neodymium based filler (MQP-14-12 manufactured by Molycorp Magnequench; average particle diameter: 50 μm) to prepare a filler dispersed liquid. This filler dispersed liquid was defoamed under a reduced pressure. Thereto were added 100.0 parts by weight of the above-mentioned prepolymer A defoamed in the same way. These components were mixed with each other and defoamed in a planetary centrifugal mixer (manufactured by Thinky Corp.) to prepare a polyurethane composition containing the magnetic filler. Next, a spacer of 0.25 mm thickness was bonded onto the adhesive polyurethane produced as described above. Thereto was then injected the polyurethane composition, and then a nip roller was used to adjust the thickness of the resultant. Thereafter, the resultant was cured at 80° C. for 1 hour to yield a polyurethane resin containing the magnetic filler. A magnetizing machine (manufactured by Denshijiki Industry Co., Ltd.) was then used to magnetize the resultant polyurethane resin at 2.0 T to yield a pressure-sensitive-adhesive-layer-attached magnetic polyurethane resin.

### Example 2

Pressure-sensitive-adhesive-layer-attached magnetic polyurethane resins were each yielded in the same way as in Example 1 except that the composition of the pressure-sensitive-adhesive layer, the thickness of the polymer matrix layer, and/or the thickness of the pressure-sensitive-adhesive layer was/were changed to one(s) described in Table 1.

### Comparative Example 1

A magnetic polyurethane resin was yielded in the same way as in Example 1 except that the yielded resin was caused not to have any pressure-sensitive-adhesive layer.

The magnetic polyurethane resin yielded in each of Examples 1 to 6 and Comparative Example 1 was used to evaluate a change in the magnetic flux density thereof, and the property stability thereof in accordance with the following methods:

### (Compressive Elastic Modulus)

In accordance with JIS K-7312, a pressure-sensitive-adhesive layer, 25.0 mm in thickness, produced in the same way as used in each of the above-mentioned examples was subjected to a compression test at room temperature and a compression velocity of 1 mm/min, using an autograph AG-X (manufactured by Shimadzu Corp.). As a test piece therefor, a right cylindrical sample was used which had a thickness of 12.5 mm and a diameter of 29.0 mm. The compressive elastic modulus thereof was gained from the resultant stress value at a strain of 2.4 to 2.6%.

### (Adhesive Force)

The above-mentioned pressure-sensitive-adhesive-layer-attached polyurethane resin was bonded to an aluminum foil piece as an adherend. In accordance with JIS Z-0237, the 180° peeling-away adhesive force thereof was measured at room temperature and a pulling velocity of 50 mm/min, using an autograph AG-X (manufactured by Shimadzu Corp.). A bonded region of the test piece was adjusted to have a width of 25 mm and a length of 50 mm.

### (Magnetic Flux Density Change)

A Hall element (EQ-430L, manufactured by Asahi Kasei Microdevices Corp.) as a detection unit was bonded to a stainless steel plate through a double-sided tape. The produced pressure-sensitive-adhesive-layer-attached magnetic polyurethane resin was bonded to the Hall-element-bonded plate from its upper surface. A pressure indenter, 50 mm×50 mm in size, was used to apply pressure thereto. When the bonded resin showed a strain of 10%, a change thereof in magnetic flux density was measured relatively to the state that no pressure was applied to the bonded resin (when the bonded resin showed a strain of 0%).

### (Sensor Property Evaluation)

The produced pressure-sensitive-adhesive-layer-attached magnetic polyurethane resin was set into a vibration tester, and then sine waves having a vibration frequency of 200 Hz and an amplitude of 0.8 mm (total amplitude: 1.6 mm) were given thereto to make a vibration test. The application of the sine waves was performed for 3 hours from each of three directions perpendicular to each other. From a change in the magnetic flux density when the resin showed a strain of 10%, between times before and after this vibration test, the property stability of the resin was gained. The number of times of the measurement was set to 10.

TABLE 1

| | | | | | | | | | Comparative |
|---|---|---|---|---|---|---|---|---|---|
| | | | Example 1 | Example 2 | Example 3 | Example 4 | Example 5 | Example 6 | Example 1 |
| Pressure- | Prepolymer | A | 100.0 | 100.0 | 100.0 | 100.0 | 100.0 | 100.0 | — |
| sensitive- | Active-hydrogen- | A | 15.0 | 15.0 | 15.0 | 6.8 | 41.4 | 15.0 | — |
| adhesive- | containing | C | 5.0 | 5.0 | 5.0 | 5.6 | 3.1 | | — |
| layer | compounds | D | | | | | | 4.2 | |
| composition | Solvent | Ethyl | 60.0 | 60.0 | 60.0 | 56.2 | 72.3 | 59.6 | — |
| | | acetate | | | | | | | |

| | | | | | | | |
|---|---|---|---|---|---|---|---|
| Catalyst | 0.12 | 0.12 | 0.12 | 0.11 | 0.14 | 0.12 | — |
| NCO index | 1.00 | 1.00 | 1.00 | 1.00 | 1.00 | 1.00 | — |
| Monool group content (meq/g) | 0.58 | 0.58 | 0.58 | 0.70 | 0.30 | 0.58 | — |

| | | | | | | | |
|---|---|---|---|---|---|---|---|
| Pressure-sensitive-adhesive-layer-attached | 0.289 | 0.107 | 0.404 | 0.294 | 0.285 | 0.101 | 0.274 |
| polymer matrix thickness (mm) | | | | | | | |
| Polymer matrix layer thickness (mm) | 0.248 | 0.015 | 0.392 | 0.216 | 0.253 | 0.017 | 0.274 |
| Pressure-sensitive-adhesive layer | 0.041 | 0.092 | 0.012 | 0.038 | 0.035 | 0.087 | — |
| thickness (mm) | | | | | | | |
| “Pressure-sensitive-adhesive layer | 0.17 | 6.13 | 0.031 | 0.18 | 0.14 | 5.12 | |
| thickness”/“polymer matrix layer thickness” | | | | | | | |
| Pressure-sensitive-adhesive layer | 0.16 | 0.16 | 0.16 | 0.08 | 4.61 | 0.23 | — |
| compressive elastic modulus (MPa) | | | | | | | |
| Adhesive force (N/10 Mm) | 1.12 | 1.18 | 0.86 | 1.16 | 0.77 | 0.92 | 0.27 |
| Property stability (%) | 8.4 | 7.8 | 10.6 | 10.1 | 11.3 | 9.6 | 18.2 |
| Magnetic flux density change (Gauss) | 0.98 | 0.34 | 1.17 | 0.87 | 0.56 | 0.30 | 0.27 |
| at strain of 10% | | | | | | | |

The magnetic polyurethane resin according to Comparative Example 1 was shifted out of position by the vibration to be very bad in property stability since the resin had no pressure-sensitive-adhesive layer. In the meantime, it is understood that the magnetic polyurethane resin according to each of Examples 1 to 6 was good in fixed-position-staying performance to be excellent in property stability. It is particularly understood in the working examples that as the thickness of their pressure-sensitive-adhesive layers was larger, the following-performance was made better at the time of the vibration test. It is also understood that as the thickness of their polymer matrix layers was larger, the magnetic filler amount contained therein was larger so that the working examples showed a larger magnetic flux density change.

### DESCRIPTION OF REFERENCE SIGNS

2: cell
3: polymer matrix layer
4: detection unit
21: external packaging body
22: electrode group
24: pressure-sensitive-adhesive layer
25: pressure-sensitive-adhesive-layer-attached polymer matrix layer

1. A sensor for detecting a deformation of a sealed secondary battery, comprising a polymer matrix layer and a detection unit,
wherein
the sealed secondary battery has at least one cell comprising a group of electrodes, and an external packaging body in which the electrode group is held,
the polymer matrix layer is located inside the external packaging body, and contains a filler in a dispersed state, this filler giving a change to an external field in response to a deformation of the polymer matrix layer, and the detection unit is located outside the external packaging body to detect a change of the external field,
the polymer matrix layer is a pressure-sensitive-adhesive-layer-attached polymer matrix layer having a pressure-sensitive-adhesive layer laminated on at least one surface of this polymer matrix layer.

2. The sensor for detecting a deformation of a sealed secondary battery according to claim 1, wherein
the polymer matrix layer comprises a magnetic filler as the filler, and
the detection unit detects a change of a magnetic field as the external field.

3. The sensor for detecting a deformation of a sealed secondary battery according to claim 1, wherein the ratio of the thickness of the pressure-sensitive-adhesive layer to the thickness of the polymer matrix layer is from 0.01 to 10.

4. The sensor for detecting a deformation of a sealed secondary battery according to claim 1, wherein the thickness of the polymer matrix layer is from 0.01 to 0.4 mm, the thickness of the pressure-sensitive-adhesive layer is from 0.005 to 0.1 mm, and the thickness of the pressure-sensitive-adhesive-layer-attached polymer matrix layer is from 0.015 to 0.5 mm.

5. The sensor for detecting a deformation of a sealed secondary battery according to claim 1, wherein the pressure-sensitive-adhesive layer has an elastic modulus of 0.01 to 5 MPa.

6. The sensor for detecting a deformation of a sealed secondary battery according to claim 1, wherein the pressure-sensitive-adhesive layer comprises a polyurethane obtained by causing an active-hydrogen-containing compound to react with an isocyanate component, and the active-hydrogen-containing compound contains a monool component.

7. The sensor for detecting a deformation of a sealed secondary battery according to claim 1, wherein the pressure-sensitive-adhesive-layer-attached polymer matrix layer is fixed onto a curved portion of the electrode group through the pressure-sensitive-adhesive layer.

8. A sealed secondary battery, comprising the sensor for detecting a deformation according to claim 1 fitted to the sealed secondary battery.

9. A method for detecting a deformation of a sealed secondary battery having at least one cell comprising a group of electrodes and an external packaging body in which the electrode group is held;
wherein
a pressure-sensitive-adhesive-layer-attached polymer matrix layer is fixed to an inside of the external packaging body;
a polymer matrix layer which the pressure-sensitive-adhesive-layer-attached polymer matrix layer has comprises a filler in a dispersed state, this filler giving a change to an external field in response to a deformation of the polymer matrix layer; and
a change of the external field which follows the deformation of the polymer matrix layer is detected, and based on the detection, the deformation of the sealed secondary battery is detected.

10. The method for detecting a deformation of a sealed secondary battery according to claim 9, wherein the polymer matrix layer comprises a magnetic filler as the filler.
